(19) United States
(12) Patent Application Publication
(10) Pub. No.: US 2009/0168380 A1
(43) Pub. Date: Jul. 2, 2009

(54) PACKAGE SUBSTRATE EMBEDDED WITH SEMICONDUCTOR COMPONENT

(75) Inventors: Shih-Ping Hsu, Hsin-Chu (TW); Kan-Jung Chia, Hsin-Chu (TW)

Correspondence Address: KNOBBE MARTENS OLSON & BEAR LLP, 2040 MAIN STREET, FOURTEENTH FLOOR, IRVINE, CA, 92614, US

(73) Assignee: Phoenix Precision Technology Corporation, Hsin-Chu (TW)

(21) Appl. No.: 12/340,445

(22) Filed: Dec. 19, 2008

(30) Foreign Application Priority Data
Dec. 31, 2007 (TW) 096151343

(51) Int. Cl. H05K 1/18

(52) U.S. Cl. 361/761

(57) ABSTRACT

A package substrate embedded with a semiconductor component is provided. A semiconductor chip is received in a cavity of a substrate body, and has electrode pads on an active surface thereof. A passivation layer is disposed on the active surface and has openings for exposing the electrode pads. An electroless plating metal layer, a first sputtering metal layer and a second sputtering metal layer are sequentially formed on the electrode pads, the openings of the passivation layer and the passivation layer surface around the openings. Contact pads are formed on the second sputtering metal layer. A first dielectric layer is disposed on the substrate body and the passivation layer. A first circuit layer is formed on the first dielectric layer. First conductive vias are formed in the first dielectric layer and electrically connected to the contact pads. The first circuit layer is electrically connected to the first conductive vias.

### FIELD OF THE INVENTION

The present invention relates to semiconductor package substrates and more particularly, to a package substrate embedded with a semiconductor component.

### BACKGROUND OF THE INVENTION

As the semiconductor packaging technology advances, there have been developed various types of packages for semiconductor components. For example, one type of semiconductor component allows a semiconductor chip having an integrated circuit (IC) to be embedded in and electrically integrated with a package substrate. This semiconductor component may desirably reduce the overall size and improve the electrical functionality thereof, and thereby becomes widely adopted.

FIGS. 1A to 1L show a conventional package substrate embedded with a semiconductor chip as disclosed in U.S. Pat. No. 6,586,276. As shown in FIG. 1A, a wafer 10 having a plurality of electrode pads 101 is provided. As shown in FIG. 1B, a passivation layer 11 is formed on the wafer 10. As shown in FIG. 1C, a plurality of openings 110 are formed in the passivation layer 11 to expose the electrode pads 101 respectively. As shown in FIG. 1D, an adhesion layer 12 is disposed over the passivation layer 11 and the electrode pads 101. As shown in FIG. 1E, then a protection layer 13 is formed on the adhesion layer 12. As shown in FIG. 1F, the wafer 10 is cut into a plurality of semiconductor chips 10a. As shown in FIG. 1G, a substrate body 14 having a cavity 140 is provided, and at least a semiconductor chip 10a is received in the cavity 140 of the substrate body 14. A bonding material 15 is filled in a gap between the semiconductor chip 10a and the cavity 140 of the substrate body 14 so as to fix the semiconductor chip 10a in position in the cavity 140. As shown in FIG. 1H, a conductive layer 16 is formed on the protection layer 13 of the semiconductor chip 10a, the bonding material 15 and the substrate body 14. As shown in FIG. 1I, then a resist layer 17 is disposed on the conductive layer 16, and is formed with a plurality of resist openings 170 corresponding in position to the electrode pads 101 respectively. As shown in FIG. 1J, a plurality of expanded pads 18 are formed on the conductive layer 16 in the resist openings 170 by electroplating. As shown in FIG. 1K, the resist layer 17 and portions of the conductive layer 16, protection layer 13 and adhesion layer 12 covered by the resist layer 17 are removed so as to expose the expanded pads 18 and the passivation layer 11, wherein the expanded pads 18 are larger than the electrode pads 101 and thus facilitate positional alignment during subsequent lamination of dielectric layers and formation of circuit layers. As shown in FIG. 1L, finally, a circuit build-up structure 19 is formed on the expanded pads 18, the passivation layer 11 and the substrate body 14. The circuit build-up structure 19 comprises at least a dielectric layer 191, a circuit layer 192 formed on the dielectric layer 191, and conductive vias 193 formed in the dielectric layer 191 and electrically connected to the expanded pads 18, wherein a plurality of conductive pads 194 are provided on a surface of the circuit build-up structure 19 and are electrically connected to the circuit layer 192. An insulating protective layer 195 is disposed on the circuit build-up structure 19, and has a plurality of openings 1950 for exposing the conductive pads 194 respectively. Regarding the conventional package substrate embedded with a semiconductor chip, before cutting the wafer 10 into the plurality of semiconductor chips 10a, it is necessary to apply the adhesion layer 12 on the passivation layer 11 and the electrode pads 101 and dispose the protection layer 13 on the adhesion layer 12. Although the adhesion layer 12 and the protection layer 13 may facilitate subsequent processing of the semiconductor chip in the substrate body, they both are formed by a sputtering process that performs blanket deposition of metal layers on the wafer 10, and the sputtered metal layers are made of different materials from the wafer 10 (which is made based on silicon), such that the wafer 10 is liable to crack when it is being cut.

Therefore, the problem to be solved here is to avoid cracking of the wafer during the cutting process as encountered in the prior art.

### SUMMARY OF THE INVENTION

In view of the above drawback in the prior art, an objective of the present invention is to provide a package substrate embedded with a semiconductor component, which can solve the cracking problem for a wafer during a cutting process.

Another objective of the present invention is to provide a package substrate embedded with a semiconductor component, so as to obtain the package substrate of good quality.

In accordance with the above and other objectives, the present invention proposes a package substrate embedded with a semiconductor component, comprising: a substrate body having at least a cavity; a semiconductor chip received and fixed in the cavity of the substrate body, the semiconductor chip having an active surface and an opposing inactive surface, wherein the active surface is formed with a plurality of electrode pads thereon, and a passivation layer is disposed on the active surface of the semiconductor chip and has a plurality of openings exposing the electrode pads respectively; an electroless plating metal layer formed on the exposed electrode pads, the openings of the passivation layer and the passivation layer surface around the openings; a first sputtering metal layer formed on the electroless plating metal layer; a second sputtering metal layer formed on the first sputtering metal layer; a plurality of contact pads formed on the second sputtering metal layer, wherein the contact pads are larger than the electrode pads; a first dielectric layer disposed on the substrate body and the passivation layer, and formed with a plurality of vias therein that expose the contact pads; and a first circuit layer formed on the first dielectric layer, and a plurality of first conductive vias formed in the vias of the first dielectric layer, wherein the first conductive vias are electrically connected to the contact pads, and the first circuit layer is electrically connected to the first conductive vias.

According to the above structure, the package substrate can further comprise a bonding material disposed in a gap between the semiconductor chip and the cavity of the substrate body, for fixing the semiconductor chip in position in the cavity of the substrate body. Alternatively, the substrate body is composed of a first sub-body and a second sub-body, and each of the first and second sub-bodies has a cavity. The semiconductor chip is received in the cavities of the first and second sub-bodies, and the bonding material is disposed between the first sub-body, the second sub-body and the cavities, so as to fix the semiconductor chip in position in the cavities. Alternatively, the semiconductor chip is placed on a carrier, and an encapsulant is formed on the carrier and the semiconductor chip, wherein the encapsulant is coplanar with the passivation layer of the semiconductor chip and exposes the passivation layer. The semiconductor chip is fixed in position in a cavity formed by the carrier and the encapsulant, and the carrier and the encapsulant constitute the substrate body.

The passivation layer is made of silicon nitride (Si₃N₄). The electroless plating metal layer is made of copper (Cu). The first sputtering metal layer is made of titanium (Ti) or titanium-tungsten (TiW). The second sputtering metal layer is made of copper (Cu).

A bonding material is disposed in a gap between the semiconductor chip and the cavity of the substrate body, for fixing the semiconductor chip in position in the cavity of the substrate body. Alternatively, the substrate body is composed of a first sub-body and a second sub-body, and each of the first and second sub-bodies has a cavity. The semiconductor chip is received in the cavities of the first and second sub-bodies, and the bonding material is disposed between the first sub-body, the second sub-body and the cavities, so as to fix the semiconductor chip in position in the cavities. Alternatively, the semiconductor chip is placed on a carrier, and an encapsulant is formed on the carrier and the semiconductor chip, wherein the encapsulant is coplanar with the passivation layer of the semiconductor chip and exposes the passivation layer. The semiconductor chip is fixed in position in a cavity formed by the carrier and the encapsulant, and the carrier and the encapsulant constitute the substrate body.

The passivation layer is made of silicon nitride (Si₃N₄). The first sputtering metal layer is made of TiW. The second sputtering metal layer is made of copper (Cu). The first dielectric layer is made of a thermal-setting material.

The first circuit layer and the first conductive vias are formed by the steps of: forming a conductive layer on the first dielectric layer, the vias of the first dielectric layer and the contact pads; disposing a second resist layer on the conductive layer, and forming a plurality of first and second openings in the second resist layer, wherein the first openings expose portions of the conductive layer on the first dielectric layer, and the second openings correspond to the contact pads and expose the contact pads, the vias of the first dielectric layer and other portions of the conductive layer on the first dielectric layer; forming the first circuit layer on the conductive layer in the first openings by electroplating, and forming the first conductive vias in the second openings by electroplating, wherein the first circuit layer is electrically connected to the first conductive vias; and removing the second resist layer and a portion of the conductive layer covered by the second resist layer.

Compared to the prior art, the package substrate embedded with a semiconductor component of the present invention is characterized in that the wafer having the electrode pads and the passivation layer is cut into the plurality of semiconductor chips, and at least one of the semiconductor chips is directly received in the cavity of the substrate body. Then, the electroless plating metal layer and the first and second sputtering metal layers are formed on the electrode pads of the semiconductor chip; afterwards, the first resist layer is disposed on the substrate body and the semiconductor chip and is formed with the resist openings for exposing the second sputtering metal layer, such that the contact pads are formed in the resist openings of the first resist layer and are electrically connected to the second sputtering metal layer. As a result, the present invention eliminates the steps of forming adhesive and protection layers on a wafer by sputtering as required in the prior art, and can firstly cut the wafer into chips and then form the electroless plating metal layer and the first and second sputtering metal layers on each of the chips, so as to provide the metal layers with good adhesion and the subsequently formed contact pads (by electroplating) of good quality. The present invention thereby effectively solves the problem of cracking of the wafer during the cutting process performed after forming the sputtered metal layers on the wafer in the prior art.

### BRIEF DESCRIPTION OF THE DRAWINGS

FIGS. 1A to 1L (PRIOR ART) are cross-sectional schematic diagrams showing a conventional package substrate embedded with a semiconductor chip;

FIGS. 2A to 2M are cross-sectional schematic diagrams showing a package substrate embedded with a semiconductor component; and

FIGS. 2C′ and 2C″ are other embodiments in addition to FIG. 2C.

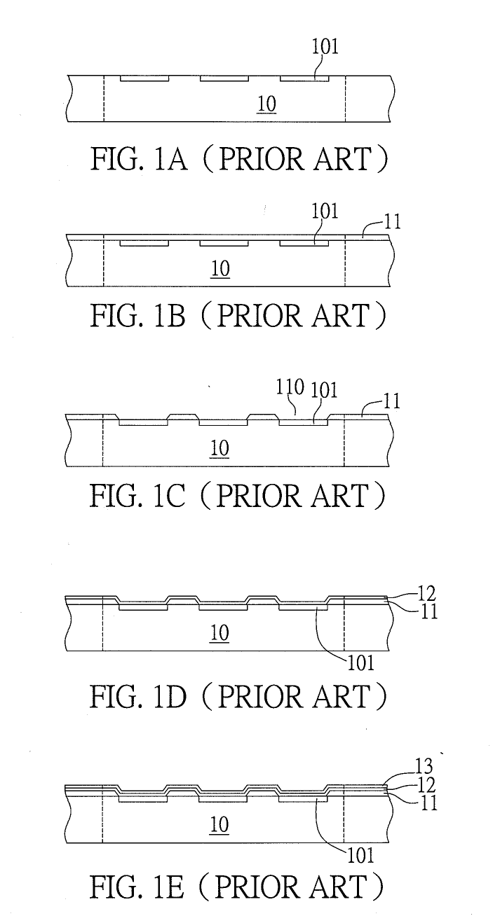

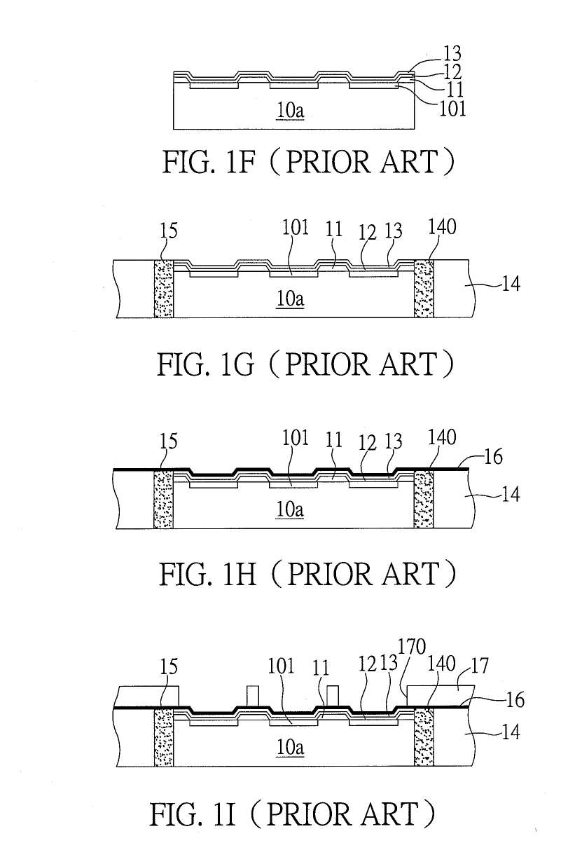

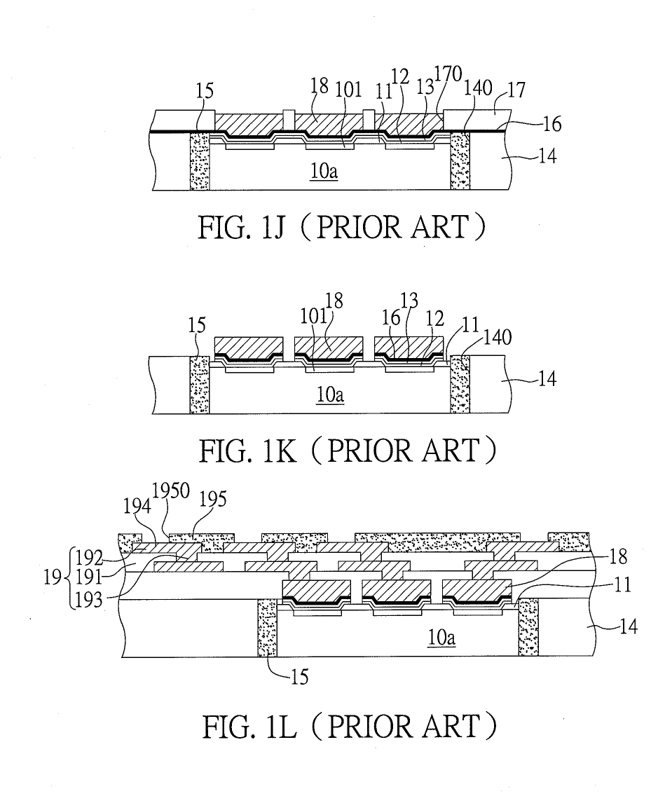

### DETAILED DESCRIPTION OF THE PREFERRED EMBODIMENT

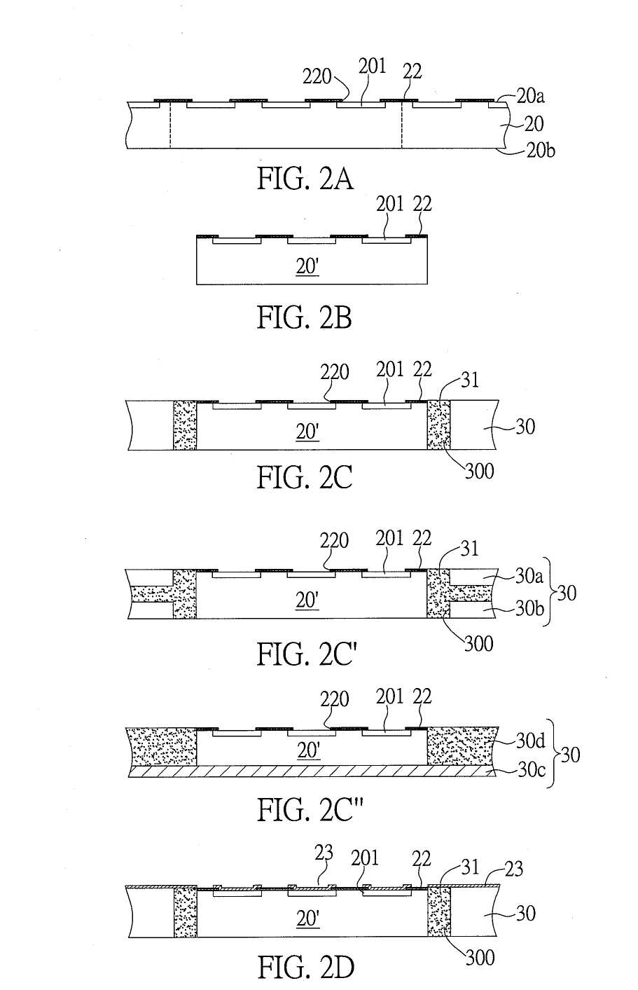

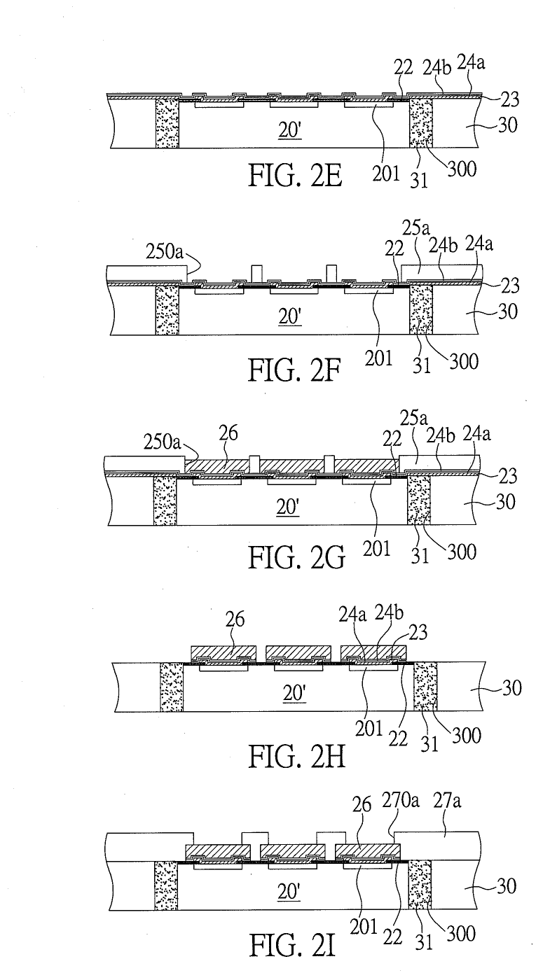

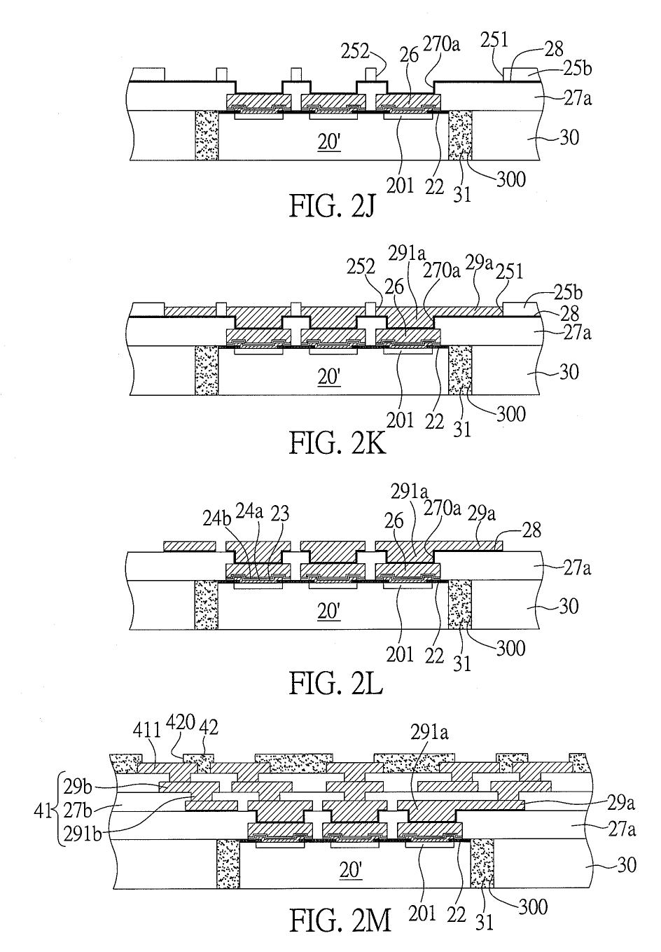

Preferred embodiments of a package substrate embedded with a semiconductor component as proposed in the present invention are described as follows with reference to FIGS. 2A to 2M and FIGS. 2C′ and 2C″. It should be understood that the drawings are schematic diagrams only showing relevant components in the present invention, and the practical component layout could be more complicated.

FIGS. 2A to 2M are cross-sectional schematic diagrams of a package substrate embedded with a semiconductor component according to the present invention.

As shown in FIG. 2A, a wafer 20 having an active surface 20a and an opposing inactive surface 20b is provided, wherein a plurality of electrode pads 201 are formed on the active surface 20a. A passivation layer 22 (which can be made of silicon nitride (Si₃N₄)) is formed on the active surface 20a of the wafer 20, and has a plurality of openings 220 for partially exposing the electrode pads 201 respectively, wherein a partial surface of each of the electrode pads 201 is exposed from a corresponding one of the openings 220 in the passivation layer 22.

As shown in FIG. 2B, the wafer 20 is cut into a plurality of semiconductor chips 20′.

As shown in FIGS. 2C, 2C′ and 2C″, a substrate body 30 having a cavity 300 is provided. The substrate body 30 is a two-layer or multi-layer circuit board formed with predetermined circuit layout. At least a semiconductor chip 20′ is received in the cavity 300 of the substrate body 30. A bonding material 31 is provided in a gap between the semiconductor chip 20′ and the cavity 300 of the substrate body 30 so as to fix the semiconductor chip 20′ in position in the cavity 300, as shown in FIG. 2C. Alternatively, the substrate body 30 comprises a first sub-body 30a and a second sub-body 30a, and each of the first and second sub-bodies 30a, 30b has a cavity 300. The semiconductor chip 20′ is received in the cavities 300 of the first and second sub-bodies 30a, 30a, and the bonding material 31 is disposed between the first and second sub-bodies 30a, 30b. The first and second sub-bodies 30a, 30b are pressed to allow the bonding material 31 to fill a gap between the semiconductor chip 20′ and the cavities 300 of the first and second sub-bodies 30a, 30b so as to fix the semiconductor chip 20′ in position in the cavities 300, as shown in FIG. 2C′. Alternatively, the semiconductor chip 20′ is placed on a carrier 30c, and an encapsulant 30d is formed on the carrier 30c and the semiconductor chip 20′ and is coplanar with the passivation layer 22 of the semiconductor chip 20′, such that the semiconductor chip 20′ is encapsulated by the encapsulant 30d while the passivation layer 22 is exposed. Accordingly, the semiconductor chip 20′ is fixed in position in a cavity 300 formed by the carrier 30c and the encapsulant 30d, and the carrier 30c and the encapsulant 30d constitute the substrate body 30, as shown in FIG. 2C″. The following description is made with reference to the embodiment shown in FIG. 2C, but is also applicable to the embodiments shown in FIGS. 2C′ and 2C″.

As shown in FIG. 2D, an electroless plating metal layer 23 is formed on the substrate body 30 and the electrode pads 201 by chemical deposition. The electroless plating metal layer 23 can be made of copper (Cu). Generally, the electroless plating metal layer 23 is only formed on the substrate body 30 and the electrode pads 201, but is not easily deposited on the passivation layer 22, such that more processes for depositing metal layers should be subsequently performed.

As shown in FIG. 2E, a first sputtering metal layer 24a (for example, made of titanium (Ti) or titanium-tungsten (TiW)) is formed on the electroless plating metal layer 23 and the passivation layer 22, and then a second sputtering metal layer 24b (for example, made of copper (Cu) is formed on the first sputtering metal layer 24a. The first sputtering metal layer 24a may solve the problem of the electroless plating metal layer 23 not easy to be deposited on the passivation layer 22, and provides the second sputtering metal layer 24b with good adhesion thereto.

As shown in FIG. 2F, a first resist layer 25a is applied on the second sputtering metal layer 24b by printing, spin-coating or attaching, and can be a photoresist layer such as dry film or liquid photoresist. Then, the first resist layer 25a is patterned by exposing and developing to form resist openings 250a corresponding in position to the electrode pads 201, such that portions of the second sputtering metal layer 24b corresponding in position to the electrode pads 201 are exposed from the resist openings 250a.

As shown in FIG. 2Q a plurality of contact pads 26 are formed on the portions of the second sputtering metal layer 24b in the resist openings 250a by electroplating, and are larger than the electrode pads 201.

As shown in FIG. 2H, the first resist layer 25a, the first and second sputtering metal layers 24a, 24b covered by the first resist layer 25a on the passivation layer 22, and the second sputtering metal layer 24b, first sputtering metal layer 24a and electroless plating metal layer 23 covered by the first resist layer 25a on the substrate body 30 are removed, so as to expose the contact pads 26.

As shown in FIG. 2I, a first dielectric layer 27a, which can be made of a thermal-setting material, is disposed on the substrate body 30, the passivation layer 22 and the contact pads 26, and a plurality of vias 270a are formed by laser in the first dielectric layer 27a at positions corresponding to the contact pads 26 so as to expose the contact pads 26. The contact pads 26 can prevent the electrode pads 201 from being damaged by the laser.

As shown in FIG. 2J, a conductive layer 28 is formed on the first dielectric layer 27a, the vias 270a and the contact pads 26, and serves as a current conducting path required in subsequent electroplating of metallic materials. The conductive layer 28 can be composed of metal, alloy, a plurality of deposited metal layers, or a conductive polymer material. Then, a second resist layer 25b is applied on the conductive layer 28 and is formed with a plurality of first openings 251 and second openings 252, wherein the first openings 251 expose portions of the conductive layer 28 on the first dielectric layer 27a, and the second openings 252 correspond to the contact pads 26 and expose the contact pads 26, the vias 270a of the first dielectric layer 27a and other portions of the conductive layer 28 on the first dielectric layer 27a. The first openings 251 can communicate with the second openings 252.

As shown in FIG. 2K, a first circuit layer 29a is formed on the conductive layer 28 in the first openings 251 by electroplating. A plurality of first conductive vias 291a are formed in the second openings 252 and the vias 270a of the first dielectric layer 27a by electroplating and are electrically connected to the contact pads 26. The first circuit layer 29a is electrically connected to the first conductive vias 291 a.

As shown in FIG. 2L, the second resist layer 25b and the conductive layer 28 covered by the second resist layer 25b are removed so as to expose the first circuit layer 29a.

As shown in FIG. 2M, a circuit build-up structure 41 is formed on the first circuit layer 29a and the first dielectric layer 27a. The circuit build-up structure 41 comprises at least a second dielectric layer 27b, a second circuit layer 29b disposed on the second dielectric layer 27b, and a plurality of conductive vias 291b formed in the second dielectric layer 27b and electrically connected to the first and second circuit layers 29a, 29b. A plurality of conductive pads 411 are provided on a surface of the circuit build-up structure 41 and are electrically connected to the second circuit layer 29b. An insulating protective layer 42 is disposed on the circuit build-up structure 41 and is formed with a plurality of openings 420 for exposing the conductive pads 411 respectively.

The present invention also provides a package substrate embedded with a semiconductor component, comprising: a substrate body 30 having at least a cavity 300; a semiconductor chip 20′ received and fixed in the cavity 300 of the substrate body 30, the semiconductor chip 20′ having an active surface 20a and an opposing inactive surface 20a, wherein the active surface 20a is formed with a plurality of electrode pads 201 thereon, and a passivation layer 22 is disposed on the active surface 20a of the semiconductor chip 20′ and has a plurality of openings 220 for exposing the electrode pads 201 respectively; an electroless plating metal layer 23 formed on the exposed electrode pads 201, the openings 220 of the passivation layer 22 and the passivation layer 22 surface around the openings 220; a first sputtering metal layer 24a formed on the electroless plating metal layer 23; a second sputtering metal layer 24b formed on the first sputtering metal layer 24a; a plurality of contact pads 26 formed on the second sputtering metal layer 24b, wherein the contact pads 26 are larger than the electrode pads 201; a first dielectric layer 27a disposed on the substrate body 30 and the passivation layer 22, and formed with a plurality of vias 270a therein for exposing the contact pads 26 respectively; and a first circuit layer 29a formed on the first dielectric layer 27a, and a plurality of first conductive vias 291a formed in the vias 270a of the first dielectric layer 27a, wherein the first conductive vias 291a are electrically connected to the contact pads 26, and the first circuit layer 29a is electrically connected to the first conductive vias 291a.

According to the above structure, the package substrate can further comprise a bonding material 31 disposed in a gap between the semiconductor chip 20′ and the cavity 300 of the substrate body 30, for fixing the semiconductor chip 20′ in position in the cavity 300 of the substrate body 30. Alternatively, the substrate body 30 is composed of a first sub-body 30a and a second sub-body 30a, and each of the first and second sub-bodies 30a, 30b has a cavity 300. The semiconductor chip 20′ is received in the cavities 300 of the first and second sub-bodies 30a, 30a, and the bonding material 31 is disposed between the first sub-body 30a, the second sub-body 30b and the cavities 300, so as to fix the semiconductor chip 20′ in position in the cavities 300. Alternatively, the semiconductor chip 20′ is placed on a carrier 30c, and an encapsulant 30d is formed on the carrier 30c and the semiconductor chip 20′, wherein the encapsulant 30d is coplanar with the passivation layer 22 of the semiconductor chip 20′ and exposes the passivation layer 22. The semiconductor chip 20′ is fixed in position in a cavity 300 formed by the carrier 30c and the encapsulant 30d, and the carrier 30c and the encapsulant 30d constitute the substrate body 30.

The passivation layer 22 is made of silicon nitride (Si₃N₄). The electroless plating metal layer 23 is made of copper (Cu). The first sputtering metal layer 24a is made of titanium (Ti) or titanium-tungsten (TiW). The second sputtering metal layer 24b is made of copper (Cu).

Therefore, in an embodiment of the package substrate embedded with a semiconductor component, the semiconductor chip 20′ is embedded in the cavity 300 of the substrate body 30 such that the overall height of the structure can be reduced. Then, the electroless plating metal layer 23 and the first and second sputtering metal layers 24a, 24b are formed on the electrode pads 201 of the semiconductor chip 20′; afterwards, afterwards, the first resist layer 25a is disposed on the substrate body 30 and the semiconductor chip 20′ received in the cavity 300. Then, the first resist layer 25a is patterned to form resist openings 250a and the contact pads 26 are electroplated in resist openings 250a and are electrically connected to the second sputtering metal layer 24b. As a result, the present invention eliminates the steps of forming adhesive and protection layers on a wafer by sputtering as in the prior art, and can firstly cut the wafer into chips and then form the electroless plating metal layer and the first and second sputtering metal layers on each of the chips, so as to provide the metal layers with good adhesion and the subsequently formed contact pads (by electroplating) of good quality. The present invention thereby effectively solves the problem of cracking of the wafer during the cutting process performed after forming the sputtered metal layers on the wafer in the prior art.

The present invention has been described using exemplary preferred embodiments. However, it is to be understood that the scope of the present invention is not limited to the disclosed arrangements. The scope of the claims, therefore, should be accorded the broadest interpretation, so as to encompass all such modifications and equivalents.

What is claimed is:

1. A package substrate embedded with a semiconductor component, comprising:
a substrate body having at least a cavity;
a semiconductor chip received and fixed in the cavity of the substrate body, the semiconductor chip having an active surface and an opposing inactive surface, wherein the active surface is formed with a plurality of electrode pads thereon, and a passivation layer is disposed on the active surface of the semiconductor chip and has a plurality of openings exposing the electrode pads respectively;
an electroless plating metal layer formed on the exposed electrode pads, the openings of the passivation layer and the passivation layer surface around the openings;
a first sputtering metal layer formed on the electroless plating metal layer;
a second sputtering metal layer formed on the first sputtering metal layer;
a plurality of contact pads formed on the second sputtering metal layer, wherein the contact pads are larger than the electrode pads;
a first dielectric layer disposed on the substrate body and the passivation layer, and formed with a plurality of vias therein that expose the contact pads; and
a first circuit layer formed on the first dielectric layer, and a plurality of first conductive vias formed in the vias of the first dielectric layer, wherein the first conductive vias are electrically connected to the contact pads, and the first circuit layer is electrically connected to the first conductive vias.

2. The package substrate embedded with a semiconductor component of claim 1, further comprising: a bonding material disposed in a gap between the semiconductor chip and the cavity of the substrate body so as to fix the semiconductor chip in position in the cavity of the substrate body.

3. The package substrate embedded with a semiconductor component of claim 1, wherein the substrate body comprises a first sub-body and a second sub-body, each of the first and second sub-bodies having a cavity, and wherein the semiconductor chip is received in the cavities of the first and second sub-bodies, and a bonding material is disposed between the first sub-body, the second sub-body and the cavities, so as to fix the semiconductor chip in position in the cavities.

4. The package substrate embedded with a semiconductor component of claim 1, wherein the semiconductor chip is placed on a carrier, and an encapsulant is formed on the carrier and the semiconductor chip, the encapsulant being coplanar with the passivation layer of the semiconductor chip and exposing the passivation layer, such that the semiconductor chip is fixed in position in a cavity formed by the carrier and the encapsulant that constitute the substrate body.

5. The package substrate embedded with a semiconductor component of claim 1, wherein the passivation layer is made of silicon nitride (Si₃N₄).

6. The package substrate embedded with a semiconductor component of claim 1, wherein the electroless plating metal layer is made of copper (Cu).

7. The package substrate embedded with a semiconductor component of claim 1, wherein the first sputtering metal layer is made of one of titanium (Ti) and titanium-tungsten (TiW).

8. The package substrate embedded with a semiconductor component of claim 1, wherein the second sputtering metal layer is made of copper (Cu).

9. The package substrate embedded with a semiconductor component of claim 1, further comprising: a circuit build-up structure formed on the first circuit layer and the first dielectric layer.

10. The package substrate embedded with a semiconductor component of claim 9, wherein the circuit build-up structure including at least a second dielectric layer, a second circuit layer disposed on the second dielectric layer, a plurality of conductive vias formed in the second dielectric layer and electrically connected to the first and second circuit layers and a plurality of conductive pads disposed on the circuit build-up structure surface for electrically connecting to the second circuit layer.

11. The package substrate embedded with a semiconductor component of claim 10, a insulating protective layer is formed on the circuit build-up structure having a plurality of openings that correspondingly expose the conductive pads.
